(19) United States
(12) Patent Application Publication
(10) Pub. No.: US 2011/0042817 A1
(43) Pub. Date: Feb. 24, 2011

(54) SOLDER JOINT STRUCTURE, AND JOINING METHOD OF THE SAME

(75) Inventors: Akio Furusawa, Osaka (JP); Shigeaki Sakatani, Osaka (JP); Hidetoshi Kitaura, Osaka (JP); Taichi Nakamura, Osaka (JP); Takahiro Matsuo, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/935,381

(22) PCT Filed: Apr. 27, 2010
(86) PCT No.: PCT/JP2010/002999

§ 371 Date: Sep. 29, 2010

(30) Foreign Application Priority Data
Apr. 30, 2009 (JP) 2009-110524 2009

(51) Int. Cl. H01L 23/532; H01L 21/60

(52) U.S. Cl. 257/772; 438/612; 257/E23.155; 257/E21.509

(57) ABSTRACT

A layer (105) of a metal having a crystal lattice different from the crystal lattice of a joining material (106) mainly containing Bi is placed on a surface (102b) of a semiconductor device (102), and a layer (104) of an element having a positive value of heat of formation of a compound with the joining material (106) is placed between the layer (105) of the metal having the crystal lattice different from the crystal lattice of the joining material (106) and the surface (102b) of the semiconductor device (102), thereby preventing the component of the layer (105) of the metal having the crystal lattice different from the crystal lattice of the joining material (106) from being diffused in the semiconductor device (102).

### TECHNICAL FIELD

The present invention relates to a solder joint structure including a joining material that does not contain lead, and particularly to the solder joint structure of a semiconductor component in which a semiconductor device of Si, GaN, or Sic and an electrode are joined to each other.

### BACKGROUND ART

A semiconductor component is mounted on a substrate using a solder material. For example, as a solder material for joining a semiconductor component such as an IGBT (Insulated Gate Bipolar Transistor) and a substrate, Sn-3 wt % Ag-0.5 wt % Cu having a melting point of 220° C. is generally used.

FIG. 5 is a schematic diagram of a semiconductor component mounted on a substrate.

When a semiconductor component 1 is mounted on a substrate 2, a dipping device of a solder dipping type is used to solder an external electrode 4 of the semiconductor component 1 to a substrate electrode 5, for example, with Sn-3 wt % Ag-0.5 wt % Cu that is a solder material 3 having a melting point of 220° C. At this point, the solder material 3 is heated to 250 to 260° C. by the dipping device, and thus the temperature inside the semiconductor component 1 sometimes reaches 250 to 260° C. The semiconductor component 1 includes a semiconductor device 6 and an electrode 7 joined to each other by a joining material 8, but if the joining material 8 melts inside the semiconductor component 1, a short-circuit, break, or a change in electrical characteristics may occur to cause a defect in a final product. Thus, the joining material 8 used inside the semiconductor component 1 needs to have a higher melting temperature than the highest temperature inside the semiconductor component 1 that is reached during soldering with the dipping device.

A joining material having a melting temperature of more than 260° C. and not containing lead, a joining material containing 90 wt % or more of Bi (hereinafter referred to as “joining material mainly containing Bi”, for example, Bi-2.5Ag having a melting point of 262° C. or Bi-0.5Cu having a melting point of 270° C.) is considered to be suitable. As another joining material, Zn is also considered, but in view of wettability or ease of joining, the joining material mainly containing Bi is suitable at present. A power semiconductor module using the joining material mainly containing Bi has been proposed (see Patent Literature 1). FIG. 6 is a sectional view of a conventional solder joint structure described in Patent Literature 1.

In FIG. 6, in a power semiconductor module 9, a joining portion 12 is provided between a power semiconductor device 10 and a conductive layer 11. The joining portion 12 uses a joining material mainly containing Bi, and a Cu layer 13 having a thickness of 0.1 to 10 μm is formed by vapor deposition on the surface of the power semiconductor device 10 on the side of the joining portion 12, which is a surface to be joined, in order to join the joining material mainly containing Bi and Si forming the power semiconductor device 10.

### CITATION LIST

### Patent Literature

Patent Literature 1: Japanese Patent Application Laid-Open No. 2007-281412

### SUMMARY OF THE INVENTION

### Technical Problem

However, since the power semiconductor device 10 is made of Si, and Cu of the Cu layer 13 placed on the surface of the power semiconductor device 10 is easily diffused in Si, Cu is diffused into the power semiconductor device 10, and the power semiconductor device 10 does not normally function, thereby reducing product yields and providing unstable quality.

The present invention solves the conventional problem, and has an object to provide a solder joint structure having stable and a joining method thereof even when a semiconductor device and an electrode are joined by a joining material mainly containing Bi.

### Solution to Problem

The present invention provides a solder joint structure in which a semiconductor device is joined to an electrode via a joining material mainly containing Bi, wherein the layer of a metal having a crystal lattice different from the crystal lattice of the joining material is placed on the surface of the semiconductor device facing the electrode, and the layer of an element having a positive value of heat of formation of a compound with the joining material is placed between the layer of the metal having the crystal lattice different from the crystal lattice of the joining material and the surface of the semiconductor device facing the electrode.

The present invention provides a solder joint structure in which a semiconductor device is joined to an electrode via a joining material mainly containing Bi, wherein the layer of a metal having a crystal lattice different from the crystal lattice of the joining material is placed on the surface of the semiconductor device facing the electrode, the layer of an element having a positive value of heat of formation of a compound with the joining material is placed between the layer of the metal having the crystal lattice different from the crystal lattice of the joining material and the surface of the semiconductor device facing the electrode, and the layer of a metal having a smaller contact angle with the joining material than the layer of the metal having the crystal lattice different from the crystal lattice of the joining material is placed between the layer of the metal having the crystal lattice different from the crystal lattice of the joining material and the joining material.

The present invention provides a joining method of a solder joint structure including: forming the layer of a metal having a crystal lattice different from the crystal lattice of a joining material mainly containing Bi on the surface of the semiconductor device facing the electrode via the layer of an element having a positive value of heat of formation of a compound with the joining material; and heating the layer of the metal having the crystal lattice different from the crystal lattice of the joining material, the layer of the metal being in contact with the joining material, and joining the semiconductor device to the electrode via the joining material, the layer of the metal having the crystal lattice different from the crystal lattice of the joining material, and the layer of the element having the positive value of heat of formation of the compound with the joining material.

The present invention provides a joining method of a solder joint structure including: forming the layer of a metal having a crystal lattice different from the crystal lattice of a joining material mainly containing Bi on the surface of the semiconductor device facing the electrode via the layer of an element having a positive value of heat of formation of a compound with the joining material; forming the layer of a metal having a smaller contact angle with the joining material than the layer of the metal having the crystal lattice different from the crystal lattice of the joining material, on the surface on the side of the electrode of the layer of the metal having the crystal lattice different from the crystal lattice of the joining material; and heating the layer of the metal having the smaller contact angle with the joining material than the layer of the metal having the crystal lattice different from the crystal lattice of the joining material, the layer of the metal having the smaller contact angle with the joining material being in contact with the joining material, and joining the semiconductor device to the electrode via the joining material, the layer of the metal having the smaller contact angle with the joining material than the layer of the metal having the crystal lattice different from the crystal lattice of the joining material, the layer of the metal having the crystal lattice different from the crystal lattice of the joining material, and the layer of the element having the positive value of heat of formation of the compound with the joining material.

### ADVANTAGEOUS EFFECTS OF INVENTION

With this configuration, the semiconductor device and the electrode can be joined by the joining material mainly containing Bi with high quality.

### BRIEF DESCRIPTION OF DRAWINGS

FIG. 1 is a sectional view of a solder joint structure according to Embodiment 1 of the present invention.

FIG. 2 shows a relationship between the thickness of a diffusion preventing layer and the defect occurrence rate of a semiconductor device according to Embodiment 1.

FIG. 3 is a sectional view of a solder joint structure according to Embodiment 2 of the present invention.

FIG. 4 shows the wetting and spreading rate of Bi with respect to each of surface materials according to Embodiment 2.

FIG. 5 is a schematic diagram of a semiconductor device mounted on a substrate.

FIG. 6 is a sectional view of a conventional solder joint structure.

### DESCRIPTION OF EMBODIMENTS

Now, a joining method of a solder joint structure according to the present invention will be described based on specific embodiments.

### Embodiment 1

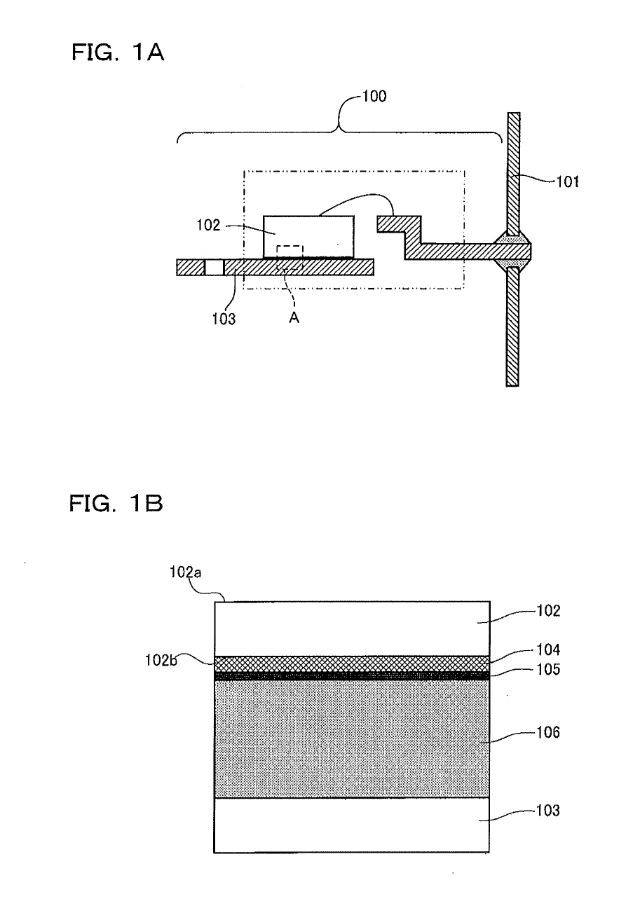

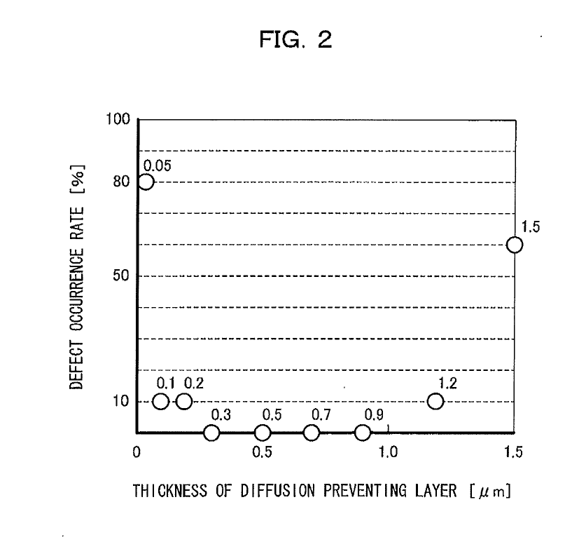

FIGS. 1 and 2 show Embodiment 1 of the present invention.

FIG. 1A shows a solder joint structure in which a semiconductor component 100 is mounted on a substrate 101. FIG. 1B is an enlarged view of a region A surrounded by a broken line in FIG. 1A.

In the semiconductor component 100, a semiconductor device 102 is joined to an electrode 103 via a joining material 106 mainly containing Bi. The joining material 106 is herein Bi-2.5 wt % Ag (having a melting point of 262° C.)

On a surface 102b of the semiconductor device 102 facing the electrode 103, a Cu layer 105 is placed as a layer of a metal having a crystal lattice different from the crystal lattice of the joining material 106. The Cu layer 105 herein has a thickness of 0.5 μm.

Between the Cu layer 105 and the surface 102b of the semiconductor device 102, a diffusion preventing layer 104 is placed as a layer of an element having a positive value of heat of formation of a compound with the joining material 106. The diffusion preventing layer 104 is herein Ta that is a metal that has a melting temperature of more than 260° C. and reduces the solid-state diffusion of Cu of the Cu layer 105 into the semiconductor device 102. The diffusion preventing layer 104 has a thickness of 0.5 μm.

More specific descriptions will be given.

The semiconductor device 102 is made of Si, and is cut out from a wafer having a diameter of 6 inches and a thickness of 0.3 mm into a size of 4.5 mm×3.55 mm. The semiconductor device 102 may be made of Ge, not limited to Si, and further may be made of a compound semiconductor such as GaN, GaAs, InP, ZnS, ZnSe, SiC, and SiGe.

A large semiconductor device 102 having a size of 6 mm×5 mm, or a small semiconductor device 102 having a size of 3 mm×2.5 mm, 2 mm×1.6 mm, or the like may be used depending on the function of the semiconductor device. The thickness of the semiconductor device 102 may differ depending on the size of the semiconductor device, is not limited to 0.3 mm, but may be 0.4 mm, 0.2 mm, 0.15 mm, or the like.

Further, a circuit pattern (not shown) is formed on a surface 102a of the semiconductor device 102 on a side opposite to the surface 102b facing the electrode 103. The diffusion preventing layer 104 formed on the surface 102b of the semiconductor device 102 is a Ta layer having a thickness of 0.5 μm formed by vapor deposition. The diffusion preventing layer 104 prevents Cu of the Cu layer 105 from being diffused into the semiconductor device 102 to impair the function of the semiconductor device 102.

The diffusion preventing layer 104 may be a metal that has a melting temperature of more than 260° C. and does not allow for the solid-state diffusion of Cu, is not limited to Ta, but may be Ti, Cr, TaN, TaC, TiN, or TiC. A plurality of layers selected from these metals may be stacked and formed. When the plurality of layers are stacked and formed, any combinations such as a Ta layer+a TaN layer, a Ta layer+a TaC layer, a Ti layer+a TiN layer, or a Cr layer+a Ta layer+a TaC layer may be used.

However, the diffusion preventing layer 104 is formed on the surface of the semiconductor device 102 facing the electrode 103, and thus requires conductivity for stable conduction. Since the conductivity of TaN and TiN is lower than the conductivity of Ta, Ti, Cr, TaC, and TiC, it is undesirable that a combination of TaN and TiN is used.

Next, the thickness of the diffusion preventing layer 104 will be described.

FIG. 2 shows a relationship between the thickness of the diffusion preventing layer and the defect occurrence rate of the semiconductor device.

The thicknesses of the Cu layer 105 and the joining material 106 are herein constant, and only the thickness of the diffusion preventing layer 104 is changed.

In FIG. 2, the abscissa axis represents the thickness of the diffusion preventing layer, and the diffusion preventing layer is Ta formed by vapor deposition. The ordinate axis represents the defect occurrence rate of the semiconductor device, and an IGBT assembled by the solder joint structure joined according to Embodiment 1 is used to conduct a high temperature test at 150° C. for 500 hours and then conduct an operation test to calculate the defect occurrence rate with the number of test samples of 10.

A thin diffusion preventing layer 104 cannot prevent Cu from entering the semiconductor device 102, which unpreferably breaks the semiconductor device 102. A thick diffusion preventing layer 104 prevents heat generated during an operation of the semiconductor device 102 from being released to the electrode 103, and the temperature of the semiconductor device 102 exceeds a heatproof temperature and the semiconductor device 102 unpreferably does not operate. A heat dissipation property for releasing heat generated by the semiconductor device 102 to the electrode can be obtained by a first expression: (heat dissipation property)=(thermal conductivity)/(thickness of diffusion preventing layer).

As is apparent from the result in FIG. 2, when the diffusion preventing layer 104 of Ta has a thickness of 0.3 to 0.9 μm, the defect occurrence rate is 0%, and a diffusion preventing effect is sufficiently obtained.

When the diffusion preventing layer 104 has a thickness of 0.1 to 0.2 μm, the defect occurrence rate is 10%, but as compared to the defect rate of 80% when the thickness is 0.05 μm, the effect can be obtained.

Meanwhile, when the diffusion preventing layer 104 has a thickness of 1.5 μm, the defect occurrence rate is unpreferably 60%. This is because an increase in thickness reduces the heat dissipation property as expressed in the first expression. When the diffusion preventing layer 104 has a thickness of 1.2 μm, the defect occurrence rate is 10%, but as compared to the defect rate of 60% when the thickness is 1.5 μm, the effect can be obtained.

Ti may be used as the diffusion preventing layer 104, but Ti has thermal conductivity of 21.9 W/m·K which is about 38% of and smaller than 57.5 W/m·K of Ta. Thus, to obtain a heat dissipation property nearly equal to the heat dissipation property of Ta, the thickness needs to be reduced to about 38% of the thickness of Ta by the first expression. In the diffusion preventing layer 104 of Ta, the defect occurrence rate is 10% when the thickness is 1.2 μm. When Ti is used as the diffusion preventing layer 104, the heat dissipation property nearly equal to the heat dissipation property of Ta can be obtained if the thickness is 0.46 μm that is 38% of 1.2 μm, and the defect occurrence rate at that time is about 10%.

Cr may be used as the diffusion preventing layer 104, but Cr has thermal conductivity of 93.9%/m·k which is about 160% of and larger than the thermal conductivity of Ta. Thus, when Cr is used as the diffusion preventing layer 104, the thickness may be increased to about 160% of the thickness of Ta.

TaC or TiC may be used as the diffusion preventing layer 104, but the thermal conductivity of C is 129 W/m·k and larger than the thermal conductivity of Ta or Ti. Thus, the thermal conductivity of TaC is larger than the thermal conductivity of Ta, and the thermal conductivity of TiC is larger than the thermal conductivity of Ti. Ta-50% C has thermal conductivity of about 90 W/m·K which is about 150% of and larger than 57.5 W/m·K of Ta. Thus, when TaC is used as the diffusion preventing layer 104, the thickness may be increased to about 150% of the thickness of Ta. In TiC, the diffusion preventing layer 104 may be similarly increased in thickness.

Further, TaN or TiN may be used as the diffusion preventing layer 104. However, the thermal conductivity of N is 0.03 W/m·k and smaller than the thermal conductivity of Ta or Ti, so that the thermal conductivity of TaN is smaller than the thermal conductivity of Ta and the thermal conductivity of TiN is smaller than the thermal conductivity of Ti. The thermal conductivity of Ta-50% N is about 28 W/m·K and is about 48% of and smaller than 57.5 W/m·K of Ta. Thus, when TaN is used as the diffusion preventing layer 104, the thickness may be reduced to about 48% of Ta. In TiN, the diffusion preventing layer 104 may be similarly reduced in thickness.

In FIG. 2, the defect rate is high when the diffusion preventing layer 104 is thin, because Cu of the Cu layer 105 placed in contact with the diffusion preventing layer 104 is diffused into the semiconductor device 102, the diffusion preventing layer 104 cannot serve to prevent the function of the semiconductor device 102 from being impaired, and Cu enters the semiconductor device 102.

For this reason, the thickness of the diffusion preventing layer 104 of Ta may be 0.1 μm to 1.2 μm. The desirable thickness of the diffusion preventing layer 104 is 0.3 to 0.9 μm at a defect occurrence rate of 0%.

When a plurality of layers such as a Ta layer+a TaN layer are formed as the diffusion preventing layer 104, the total thickness of the plurality of layers is preferably the thickness of the diffusion preventing layer in terms of a heat dissipation property.

When the diffusion preventing layer 104 is thick, heat generated during an operation of the semiconductor device 102 cannot be released to the electrode 103, the temperature of the semiconductor device 102 exceeds the heatproof temperature, and the semiconductor device 102 unpreferably does not operate. Thus, the appropriate upper limit value of thickness of Cr, TaC, and TiC is the upper limit value of thickness of Ta.

Next, the Cu layer 105 will be described.

The Cu layer 105 having a thickness of 0.5 μm formed on the diffusion preventing layer 104 by vapor deposition is formed to ensure joining to the joining material 106 mainly containing Bi. The Cu layer 105 may be formed by sputtering, electrolytic plating, chemical plating, or deposition, not limited to vapor deposition.

Since the Cu layer 105 is in contact with the joining material 106 mainly containing Bi, the Cu layer 105 melts into the joining material 106 mainly containing Bi. Thus, if the Cu layer 105 significantly melts, the Cu layer 105 is lost and the diffusion preventing layer 104 is exposed. In this case, the diffusion preventing layer 104 and Bi rapidly react, the diffusion preventing layer 104 is lost, and Si of the semiconductor device 102 is exposed. Since Si and Bi are not joined, a defect due to delamination occurs when the diffusion preventing layer 104 is exposed. Thus, the Cu layer 105 needs to have a thickness such that the Cu layer 105 is not lost even if heated to 320° C. in a state where the Cu layer 105 is in contact with the joining material 106 mainly containing Bi.

Table 1 below shows a relationship between the thicknesses of the Cu layer 105 before and after joining, and shows the amount of the Cu layer having melted into Bi.

TABLE 1

| Thickness of Cu | Thickness of Cu | Amount of |
|---|---|---|
| layer before | layer after | reduction of Cu |
| joining | joining | layer |
| 0.1 μm | 0 μm | 0.1 μm |
| 0.2 μm | 0.08 μm | 0.12 μm |
| 0.3 μm | 0.26 μm | 0.04 μm |
| 0.5 μm | 0.42 μm | 0.08 μm |
| 0.7 μm | 0.65 μm | 0.05 μm |
| 1.0 μm | 0.92 μm | 0.08 μm |
| 1.5 μm | 1.42 μm | 0.08 μm |

In Table 1, a Cu layer is formed by vapor deposition on a Si piece having a size of 5 mm×5 mm and a thickness of 0.3 mm, and the thickness is set as the thickness of the Cu layer before joining. The thickness is the average value of thicknesses measured at 10 spots. A sample was prepared in which a Bi layer having a thickness of 0.03 mm is formed on the Cu layer by vapor deposition, heated to 320° C. in a hydrogen atmosphere, held for 60 seconds, and then cooled to a room temperature, and the thickness of the Cu layer after joining was measured. A numerical value obtained by subtracting the thickness of the Cu layer after joining from the thickness of the Cu layer before joining represents the amount of reduction of the Cu layer by melting into Bi.

When the thickness of the Cu layer 105 before joining is 0.2 μm, the Cu layer of 0.08 μm remains after joining, but when the thickness of the Cu layer before joining is 0.1 μm, the Cu layer is lost after joining. Thus, the thickness of the Cu layer before joining needs to be 0.2 μm more than 0.1 μm such that the Cu layer 105 after joining is not lost. However, when the thickness of the Cu layer before joining is 0.2 μm, the thickness of the Cu layer after joining is reduced to 0.1 μm or less, and in view of the accuracy variations (about 0.1 μm) of the thickness, the thickness of the Cu layer 105 before joining is desirably 0.3 μm or more.

When the thickness of the Cu layer 105 before joining exceeds 2 μm, chipping and delamination of a Cu vapor deposited film occurs due to dicing in cutting out from a wafer, and thus the thickness of the Cu layer 105 before joining is desirably 2 μm or less. For this reason, the thickness of the Cu layer 105 may be 0.2 μm to 2 μm, and is desirably 0.3 μm to 2 μm.

When a generally used Ni layer needs to be formed as the diffusion preventing layer of Cu, the Ni layer is preferably placed on the side of the semiconductor device 102 of the Cu layer to prevent Ni and Bi from reacting to generate a compound.

Next, the joining material 106 will be described.

The joining material 106 contains 2.5 wt %, of Ag and the balance Bi except for inevitable impurities, but the composition of the joining material 106 is not limited to this. However, the upper limit of heating temperature of a general die bonding device for joining the semiconductor device 102 to the electrode 103 is 350° C. to 400° C., and the joining material 106 is required to melt at 350° C. or less.

The melting temperature of Bi is 271° C., adding Ag to Bi reduces a liquid phase temperature, and a eutectic temperature of 262° C. is reached at 2.5 wt %. If Ag is further added, 350° C. is reached at 9 wt %, and the upper limit of the heating temperature is reached. If Cu is added to Bi, a eutectic temperature of 270° C. is reached at 0.5 wt %. If Cu is further added, 350° C. is reached at 1 wt %, and the upper limit of the heating temperature is reached. With respect to Bi, the lower limit values of Ag and Cu are desirably 0.1 wt %. Table 2 shows the compositions of other joining materials in this embodiment.

TABLE 2

| | | | | Melting |
|---|---|---|---|---|
| | Cu | Ag | Bi | temperature |
| Composition 1 | 1.0 wt % | 0 wt % | Balance | 350° C. |
| Composition 2 | 0.8 wt % | 0 wt % | Balance | 300° C. |
| Composition 3 | 0 wt % | 5.0 wt % | Balance | 295° C. |
| Composition 4 | 0 wt % | 1.0 wt % | Balance | 268° C. |
| Composition 5 | 0.5 wt % | 2.0 wt % | Balance | 265° C. |
| Composition 6 | 0.2 wt % | 0.4 wt % | Balance | 270° C. |
| Composition 7 | 0 wt % | 0.1 wt % | Balance | 269° C. |
| Composition 8 | 0 wt % | 2.5 wt % | Balance | 262° C. |
| Composition 9 | 0.5 wt % | 1 wt % | Balance | 264° C. |
| Composition 10 | 0.8 wt % | 0 wt % | Balance | 277° C. |
| Composition 11 | 0 wt % | 5 wt % | Balance | 301° C. |
| Composition 12 | 0.1 wt % | 2 wt % | Balance | 282° C. |
| Composition 13 | 0 wt % | 9 wt % | Balance | 320° C. |

As is apparent from Table 2, compositions 1 to 13 are joining materials that have a melting temperature of 350° C. or less, and contain one or more elements selected from 0.1 to 1 wt % of Cu and 0.1 to 9 wt % of Ag, and the balance Bi. In the joining material 106, any composition may be used within a range of a melting temperature of 350° C. or less.

With such a configuration, the diffusion preventing layer 104 can prevent Cu from being diffused into the semiconductor device 102, and thus the joining material 106 mainly containing Bi can join the semiconductor device 102 and the electrode 103 with high quality.

### Embodiment 2

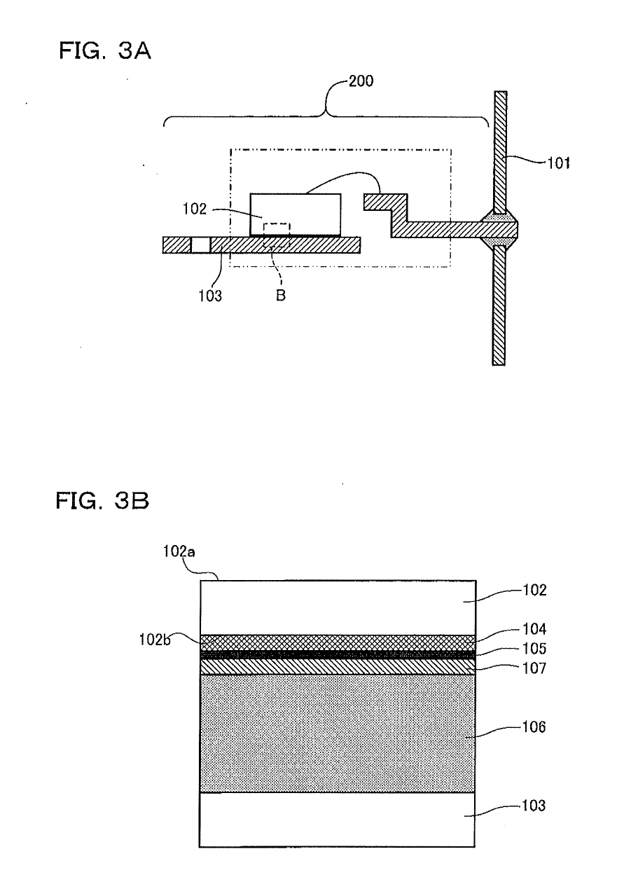

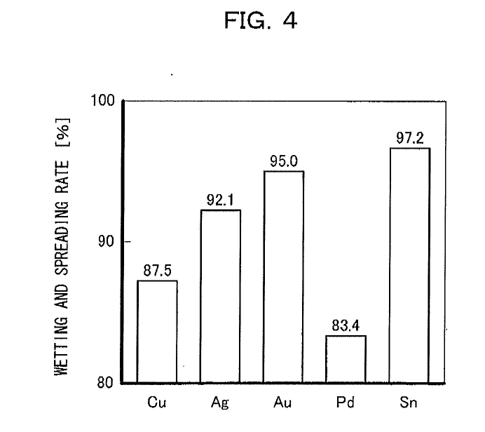

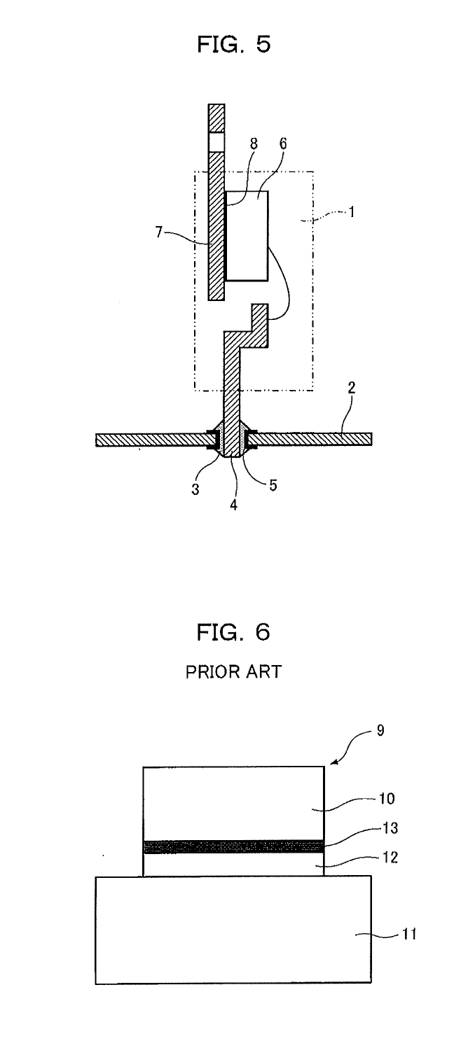

FIGS. 3 and 4 show Embodiment 2 of the present invention.

The same components as in the solder joint structure in Embodiment 1 will be denoted by the same reference numerals.

FIG. 3A shows a solder joint structure in which a semiconductor component 200 is mounted on a substrate 101. FIG. 3B is an enlarged view of a region B surrounded by a broken line in FIG. 3A.

The solder joint structure in Embodiment 2 is different from the solder joint structure in Embodiment 1 in that an Ag layer 107 as the layer of a metal having a smaller contact angle with a joining material 106 than a Cu layer 105 as the layer of a metal different from the joining material 106 is further placed between the Cu layer 105 and the joining material 106 facing an electrode.

In FIG. 3B, on the side of a semiconductor device 102 facing an electrode 103, a diffusion preventing layer 104 having a thickness of 0.5 μm, the Cu layer 105 having a thickness of 0.5 μm, and the Ag layer 107 having a thickness of 0.7 μm are placed in order.

The semiconductor device 102 in which the diffusion preventing layer 104, the Cu layer 105, and the Ag layer 107 are placed in order is joined to the electrode 103 by the joining material 106 containing Bi-2.5 wt % Ag (having a melting point of 262° C.).

The diffusion preventing layer 104 and the Cu layer 105 in the solder joint structure of Embodiment 2 of the present invention have the same configurations as the diffusion preventing layer 104 and the Cu layer 105 in the solder joint structure of Embodiment 1.

Next, the Ag layer 107 will be described.

On the surface of the Cu layer 105 facing the electrode 103, the Ag layer 107 having a thickness of 0.7 μm is formed by vapor deposition to hold a joining property to the joining material mainly containing Bi. The Ag layer 107 may be formed by sputtering, electrolytic plating, chemical plating, or deposition, not limited to vapor deposition.

The reason for placing the Ag layer 107 will be described.

Since Cu and Bi have poor wettability, joining Cu and Bi requires physical assistance such as pressurizing or scrubbing. Thus, a surface material having good wettability with Bi is desirably placed on a side where Cu is joined to the joining material mainly containing Bi. This allows Cu and Bi to be joined without physical assistance. Surface materials that can be formed by vapor deposition include Ag, Au, Pd, and Sn.

FIG. 4 shows the wetting and spreading rate of Bi with respect to each surface material.

A Bi ball having a diameter of 0.9 mm is partly cut away by 0.1 mm to form a plain. Then, a surface material having a size of 10 mm×10 mm and a thickness of 0.5 mm is prepared, and the Bi ball is placed on the surface material so that the plain of the Bi ball is in contact with the surface material. This sample was heated to 320° C. in a hydrogen atmosphere, held for 60 seconds, and then cooled to a room temperature, and the thickness of Bi was measured.

The wetting and spreading rate is calculated by ((height of Bi ball)−(thickness of Bi))/(height of Bi ball). Though Cu is described for comparison, Sn, Au, and Ag have higher wetting and spreading rates than Cu. However, Sn is unsuitable because Sn generates, together with Bi, Sn-58% Bi having a melting point of 138° C. and thus melts if used in a semiconductor component heated to 250° C. when the semiconductor component is mounted on a substrate. When the unit price of Ag per gram is 1, the unit price of Au is 74 and high, and thus Au is unsuitable for commercial use. Thus, Ag that has a higher wetting and spreading rate than Cu and is cheaper than Au is preferably used.

Table 3 shows a relationship between the thicknesses of the Ag layer 107 before and after joining.

TABLE 3

| Thickness of Ag | Thickness of Ag | Amount of |
|---|---|---|
| layer before | layer after | reduction of Ag |
| joining | joining | layer |
| 0.1 μm | 0 μm | 0.1 μm |
| 0.2 μm | 0 μm | 0.2 μm |
| 0.5 μm | 0.42 μm | 0.08 μm |
| 0.7 μm | 0.51 μm | 0.19 μm |
| 1.0 μm | 0.93 μm | 0.07 μm |
| 1.5 μm | 1.38 μm | 0.12 μm |

In Table 3, the Ag layer 107 is formed by vapor deposition on a Si piece having a size of 5 mm×5 mm and a thickness of 0.3 mm, and the thickness is set as the thickness of the Ag layer before joining. A sample in which a Bi layer having a thickness of 0.03 mm was formed on the Ag layer by vapor deposition was prepared, heated to 320° C. in a hydrogen atmosphere, held for 60 seconds, and then cooled to a room temperature, and the thickness of the Ag layer after joining was measured.

When the thickness of the Ag layer 107 before joining is more than 0.5 μm, the Ag layer 107 remains after joining, but when the thickness of the Ag layer 107 before joining is 0.2 μm or less, the Ag layer 107 is lost after joining. The thickness of the Ag layer 107 before joining needs to be more than 0.2 μm and 0.5 μm or less such that the Ag layer 107 after joining is not lost, and thus the thickness of the Ag layer before joining is desirably 0.5 μm or more.

The Ag layer is placed for ensuring wettability with Bi, and the wettability with Bi is ensured even when the thickness of the Ag layer before joining is 0.2 μm or less, and thus the thickness of the Ag layer before joining may be 0.2 μm. However, when the thickness of the Ag layer before joining is 0.1 μm, three pin holes per 10 μm² are identified in the surface of the Ag layer, and the Cu layer may be undesirably exposed.

When the Ag layer 107 is thick, a problem such as a warp in the semiconductor device 102 is supposed. Thus, next, the thickness of the Ag layer 107 was changed and a relationship between warps in wafers and cutting burrs was checked. Table 4 shows the relationship between warps in wafers and cutting burrs when the thickness of the Ag layer 107 is changed.

TABLE 4

| Thickness of Ag | | |
|---|---|---|
| layer before | | |
| joining | Warp in wafer | Cutting burr |
| 0.1 μm | No | No |
| 0.2 μm | No | No |
| 0.5 μm | No | No |
| 0.7 μm | No | No |
| 1.0 μm | No | No |
| 1.5 μm | No | No |
| 3.0 μm | No | Yes |
| 4.5 μm | No | Yes |
| 6.0 μm | Yes | Yes |

The wafer is Si having a diameter of 6 inches and a thickness of 0.3 mm. The Ag layer 107 is formed on one surface of the wafer by vapor deposition. Vapor deposition forms a film with a material having a different coefficient of linear expansion on the one surface of the wafer under high-temperature environment, and the wafer is warped when returned to a room temperature. When warped, the wafer disadvantageously cannot be processed by a dicing device in a subsequent step. Further, when the vapor deposited film is thick, a burr of the vapor deposited film occurs on a cut surface when the wafer is cut by the dicing device. The burr remains after joining to an electrode to form a stress concentration portion, which may reduce the reliability of a product.

When the thickness of the Ag layer before joining is the wafer is warped and cannot be processed in a subsequent step, and thus the thickness of the Ag layer before joining is 4.5 μm or less. When the thickness of the Ag layer before joining is 3 μm, a cutting burr may occur to reduce reliability, and thus the thickness of the Ag layer before joining is desirably 1.5 μm or less.

As described above, the thickness of the Ag layer 107 may be 0.2 μm to 4.5 μm, and desirably 0.5 μm to 1.5 μm. When the thickness of the Ag layer 107 before joining is 0.2 μm or more and less than 0.5 μm, the Ag layer 107 is partly lost after joining, and thus the solder joint structure includes an area made up of a semiconductor device, a diffusion preventing layer, a Cu layer, and a joining material. Since the Ag layer 107 melts into the joining material mainly containing Bi, Ag may be detected from the joining material by an elementary analysis such as energy dispersive X-ray spectrometry (EDX), electron probe microanalyzer (EPMA), or X-ray photoelectron spectroscopy.

Table 5 shows the configurations and product yields of examples of the present invention and comparative examples.

TABLE 5

| | Diffusion preventing | | | | | |
|---|---|---|---|---|---|---|
| | layer | | Cu layer | Ag layer | | Product |
| | Component | Thickness | thickness | thickness | Joining material | yield |
| Example 1 | Ta | 0.5 μm | 0.5 μm | 0.7 μm | Bi—2.5 wt % Ag | Excellent |
| | | | | | | 100% |
| Example 2 | Ta | 0.4 μm | 1.0 μm | 0.3 μm | Bi—1.0 wt % Ag—0.5 wt % | Excellent |
| | (First layer) | | | | Cu | 100% |
| | TaC | 0.3 μm | | | | |
| | (Second layer) | | | | | |
| Example 3 | TiC | 1.0 μm | 1.2 μm | 1.0 μm | Bi—0.8 wt % Cu | Good 95% |
| Example 4 | Ti | 0.5 μm | 0.5 μm | 0.7 μm | Bi—5 wt % Ag | Good 95% |
| | (First layer) | | | | | |
| | Ni | 0.5 μm | | | | |
| | (Second layer) | | | | | |
| Example 5 | Ti | 0.3 μm | 1.8 μm | 0.5 μm | Bi—0.1 wt % Cu—2 wt | Good 95% |
| | | | | | % Ag | |
| Example 6 | Cr | 1.0 μm | 0.8 μm | 2.0 μm | Bi—9 wt % Ag | Good 90% |
| Example 7 | TaC | 0.8 μm | 2.0 μm | 1.2 μm | Bi—0.1 wt % Ag | Good 90% |

| | | | | | |
|---|---|---|---|---|---|
| Comparative | No | 500 μm | 1.0 μm | Bi | Poor 15% |
| example 1 | | | | | |
| Comparative | No | 500 μm | No | Bi | Poor 10% |
| example 2 | | | | | |

In the product yield, an IGBT assembled by the solder joint structure joined according to each configuration with the number of test samples of 20 is used to conduct a high temperature test at 150° C. for 500 hours and then conduct an operation test to calculate defect occurrence rates. As is apparent from Table 5, Examples 1 to 7 are solder joint structures including a semiconductor device, an electrode placed to face the semiconductor device, and a joining material mainly containing Bi connecting the semiconductor device and the electrode, and in the solder joint structure, a diffusion preventing layer, a Cu layer, and an Ag layer are placed in order on the surface of the semiconductor device facing the electrode, providing high product yields and stable quality.

With such a configuration, the diffusion preventing layer 104 can prevent the semiconductor device 102 from being broken by the diffusion of the Cu layer 105 into the semiconductor device 102. Further, the Ag layer 107 ensures wettability with the joining material 106, and even if the Ag layer 107 melts into the joining material 106 with heat of 320° C. in a die bonding process and is lost, the Cu layer 105 can join the semiconductor device 102 to the joining material 106.

### INDUSTRIAL APPLICABILITY

The solder joint structure of the present invention improves the reliability of a semiconductor package such as a power semiconductor or a low-power transistor.

1. A solder joint structure in which a semiconductor device is joined to an electrode via a joining material mainly containing Bi,
wherein a layer of a metal having a crystal lattice different from a crystal lattice of the joining material is placed on a surface of the semiconductor device facing the electrode, and
a layer of an element having a positive value of heat of formation of a compound with the joining material is placed between the layer of the metal having the crystal lattice different from the crystal lattice of the joining material and the surface of the semiconductor device facing the electrode.

2. A solder joint structure in which a semiconductor device is joined to an electrode via a joining material mainly containing Bi,
wherein a layer of a metal having a crystal lattice different from a crystal lattice of the joining material is placed on a surface of the semiconductor device facing the electrode,
a layer of an element having a positive value of heat of formation of a compound with the joining material is placed between the layer of the metal having the crystal lattice different from the crystal lattice of the joining material and the surface of the semiconductor device facing the electrode, and
a layer of a metal having a smaller contact angle with the joining material than the layer of the metal having the crystal lattice different from the crystal lattice of the joining material is placed between the layer of the metal having the crystal lattice different from the crystal lattice of the joining material and the joining material.

3. The solder joint structure according to claim 1, wherein the layer of the metal having the crystal lattice different from the crystal lattice of the joining material is Cu, and the layer of the element having the positive value of heat of formation of the compound with the joining material is one or more materials selected from Ta, Ti, Cr, TaN, TaC, TiN, and TiC.

4. The solder joint structure according to claim 1, wherein the joining material contains one or more elements selected from 0.1 to 1 wt % of Cu and 0.1 to 9 wt % of Ag, and a balance Bi except for inevitable impurities.

5. A joining method of a solder joint structure comprising:
forming a layer of a metal having a crystal lattice different from a crystal lattice of a joining material mainly containing Bi on a surface of the semiconductor device facing the electrode via a layer of an element having a positive value of heat of formation of a compound with the joining material; and
heating the layer of the metal having the crystal lattice different from the crystal lattice of the joining material, the layer of the metal being in contact with the joining material, and joining the semiconductor device to the electrode via the joining material, the layer of the metal having the crystal lattice different from the crystal lattice of the joining material, and the layer of the element having the positive value of heat of formation of the compound with the joining material.

6. A joining method of a solder joint structure comprising:
forming a layer of a metal having a crystal lattice different from a crystal lattice of a joining material mainly containing Bi on a surface of the semiconductor device facing the electrode via a layer of an element having a positive value of heat of formation of a compound with the joining material;
forming a layer of a metal having a smaller contact angle with the joining material than the layer of metal having the crystal lattice different from the crystal lattice of the joining material, on a surface on a side of the electrode of the layer of the metal having the crystal lattice different from the crystal lattice of the joining material; and
heating the layer of the metal having the smaller contact angle with the joining material than the layer of the metal having the crystal lattice different from the crystal lattice of the joining material, the layer of the metal having the smaller contact angle with the joining material being in contact with the joining material, and joining the semiconductor device to the electrode via the joining material, the layer of the metal having the smaller contact angle with the joining material than the layer of the metal having the crystal lattice different from the crystal lattice of the joining material, the layer of the metal having the crystal lattice different from the crystal lattice of the joining material, and the layer of the element having the positive value of heat of formation of the compound with the joining material.

7. The solder joint structure according to claim 2, wherein the layer of the metal having the crystal lattice different from the crystal lattice of the joining material is Cu, and the layer of the element having the positive value of heat of formation of the compound with the joining material is one or more materials selected from Ta, Ti, Cr, TaN, TaC, TiN, and TiC.

8. The solder joint structure according to claim 2, wherein the joining material contains one or more elements selected from 0.1 to 1 wt % of Cu and 0.1 to 9 wt % of Ag, and a balance Bi except for inevitable impurities.
